(19) United States
(12) Patent Application Publication
(10) Pub. No.: US 2013/0278570 A1
(43) Pub. Date: Oct. 24, 2013

(54) GATE DRIVING CIRCUIT AND DISPLAY APPARATUS HAVING THE SAME

(71) Applicant: SAMSUNG DISPLAY CO., LTD., Yongin-City (KR)

(72) Inventors: Kyung-Ho PARK, Asan-si (KR); Jae-Won KIM, Asan-si (KR); Seung-Soo BAEK, Suwon-si (KR); Dong-Hyun YOO, Asan-si (KR)

(73) Assignee: SAMSUNG DISPLAY CO., LTD., YONGIN-CITY (KR)

(21) Appl. No.: 13/684,024

(22) Filed: Nov. 21, 2012

(30) Foreign Application Priority Data
Apr. 24, 2012 (KR) 10-2012-0042562

(51) Int. Cl. G09G 5/00; H03K 17/94

(52) U.S. Cl. CPC G09G 5/00; H03K 17/94
USPC 345/204; 327/109

(57) ABSTRACT

A gate driving circuit includes first to n-th gate clock lines, first to m-th selection lines, a holding control line, a voltage line and a plurality of stages. The first to n-th gate clock lines transfer first to n-th gate clock signals. The first to m-th selection lines transfer first to m-th gate selection signals. The holding control line transfers a holding control signal. The voltage line transfers a gate-off voltage. The stages outputs a plurality of gate signals, each stage outputs a high voltage of a gate clock signal as a gate-on voltage of a gate signal in response to a high voltage of a gate selection signal, and outputs the gate-off voltage in response to a high voltage of the holding control signal.

This application claims priority from, and the benefit of, Korean Patent Application No. 10-2012-0042562, filed on Apr. 24, 2012, which is hereby incorporated by reference for all purposes as if fully set forth herein.

### BACKGROUND OF THE INVENTION

1. Field of the Invention

Exemplary embodiments of the present invention relate generally to flat panel displays. More particularly, exemplary embodiments of the present invention relate to a gate driving circuit for simplifying a circuit design, and a display apparatus having the above-mentioned gate driving circuit.

2. Description of the Related Art

Recent efforts in display design have been directed toward reducing manufacturing costs and the total size of display panel modules. To accomplish this, efforts have been directed toward development of amorphous silicon gate (ASG) technology, in which a gate driving circuit is formed in a peripheral area of a panel and a switching device is disposed in a display area of a panel at the same time.

The gate driving circuit typically includes the ASG circuit and a plurality of signal lines transferring driving signals to the ASG circuit. The gate driving circuit is formed in a peripheral area of the display panel so that manufacturing costs and the total size of a panel module may be decreased. However, this also has the drawback of increasing the bezel width of the display device.

### BRIEF SUMMARY OF THE INVENTION

Exemplary embodiments of the present invention provide a gate driving circuit having a simplified circuit design.

Exemplary embodiments of the present invention also provide a display apparatus including the gate driving circuit.

According to an exemplary embodiment of the invention, there is provided a gate driving circuit, where the gate driving circuit includes first to n-th gate clock lines, first to m-th selection lines, a holding control line, a voltage line and a plurality of stages. The first to n-th gate clock lines are configured to transfer first to n-th gate clock signals (‘n’ is a natural number). The first to m-th selection lines are configured to transfer first to m-th gate selection signals (‘m’ is a natural number). The holding control line is configured to transfer a holding control signal. The voltage line is configured to transfer a gate-off voltage. The stages output a plurality of gate signals, each stage being configured to output a high voltage of one of the gate clock signals as a gate-on voltage of the gate signal in response to the high voltage of one of the gate selection signals, and is configured to output the gate-off voltage in response to a high voltage of the holding control signal.

In an exemplary embodiment, each stage may include a first transistor comprising a control part configured to receive one of the gate selection signals, an input part configured to receive one of the gate clock signals and an output configured to output one of the gate signals. Each stage may also include a second transistor comprising a control part configured to receive the holding control signal, an input part configured to receive the gate-off voltage and an output part configured to output one of the gate signals.

In an exemplary embodiment, the holding control line may include a first holding line electrically connected to an odd-numbered one of the stages to transfer a first holding control signal, and a second holding line electrically connected to an even-numbered one of the stages to transfer a second holding control signal having a phase opposite to a phase of the first holding control signal.

In an exemplary embodiment, the gate clock signals may each comprise a first pulse having a width corresponding to one horizontal period, and the gate selection signals may each comprise a second pulse having a width corresponding to n horizontal periods.

In an exemplary embodiment, ones of the first pulses can be successively emitted during each of n consecutive horizontal periods, and the second pulses can be collectively emitted during one frame period.

In an exemplary embodiment, successive ones of the first to n-th gate clock signals may be sequentially delayed by one horizontal period and successive ones of the first to m-th gate selection signals may be sequentially delayed by n horizontal periods.

In an exemplary embodiment, the high voltage of the gate selection signal may be higher than the high voltage of the gate clock signal.

In an exemplary embodiment, each of the gate clock lines may be connected to m consecutive stages and each selection line may be connected to n stages which are not consecutively arranged.

In an exemplary embodiment, each of the gate clock lines may be connected to m stages which are not consecutive and each of the selection lines may be connected to n stages which are consecutively arranged.

According to still another exemplary embodiment of the invention, there is provided a display apparatus. The display apparatus includes a display panel, the display panel a data driving circuit and a gate driving circuit. The display panel includes a display area and a peripheral area surrounding the display area, including a plurality of data lines and a plurality of gate lines crossing the data lines. The data driving circuit is configured to provide the data lines with a data signal. The gate driving circuit is disposed in the peripheral area, and is configured to provide the gate lines with a plurality of gate signals. The gate driving circuit includes first to n-th gate clock lines configured to transfer first to n-th gate clock signals (‘n’ is a natural number), first to m-th selection lines configured to transfer first to n-th gate selection signals (‘m’ is a natural number), a holding control line configured to transfer a holding control signal, a voltage line configured to transfer a gate-off voltage, and a plurality of stages configured to output a plurality of gate signals, each stage configured to output a high voltage of one of the gate clock signals as a gate signal in response to a high voltage of one of the gate selection signals, and configured to output the gate-off voltage in response to a high voltage of the holding control signal.

In an exemplary embodiment, the display apparatus may further include a timing control part configured to provide the gate driving circuit with the gate clock signal, the gate selection signal and the holding control signal.

In an exemplary embodiment, the gate driving circuit may be configured to sequentially provide the display panel with m gate signals during a sub period during which the gate selection signal has a high voltage, and the data driving circuit may be configured to provide the data signals to pixels during the sub period, the pixels being connected to n gate lines which receives n gate signals.

In an exemplary embodiment, wherein each stage may further comprise a first transistor comprising a control part configured to receive the gate selection signal, an input part configured to receive the gate clock signal and an output part configured to output the gate signal, and a second transistor comprising a control part configured to receive the holding control signal, an input part configured to receive the gate low voltage and an output part configured to output the gate signal.

In an exemplary embodiment, wherein the holding control line may comprise a first holding line electrically connected to odd-numbered ones of the stages, and configured to transfer a first holding control signal, as well as a second holding line electrically connected to even-numbered ones of the stages, and configured to transfer a second holding control signal having a phase opposite to the first holding control signal.

In an exemplary embodiment, the gate clock signals may each comprise a first pulse having a width corresponding to one horizontal period, and the gate selection signals may each comprise a second pulse having a width corresponding to n horizontal periods.

In an exemplary embodiment, ones of the first pulses may be successively emitted during each of n consecutive horizontal periods, and the second pulses may be collectively emitted during one frame period.

In an exemplary embodiment, successive ones of the first to n-th gate clock signals may be sequentially delayed by one horizontal period, and successive ones of the first to m-th gate selection signals may be sequentially delayed by n horizontal periods.

In an exemplary embodiment, the high voltage of the gate selection signal may be higher than the high voltage of the gate clock signal.

In an exemplary embodiment, each of the clock lines may be connected to m consecutive stages and each selection line may be connected to n stages which are not consecutive.

In an exemplary embodiment, each of the clock lines may be connected to m stages which are not consecutive and each selection line may be connected to n consecutive stages.

According to the present invention, a gate driving circuit includes only two thin film transistors, so that the area taken up by the gate driving circuit may be decreased. Therefore, the display apparatus may have a bezel of a narrow width.

### BRIEF DESCRIPTION OF THE DRAWINGS

The above and other features and advantages of the present invention will become more apparent by describing in detailed exemplary embodiments thereof with reference to the accompanying drawings, in which:

FIG. 1 is a block diagram illustrating an exemplary embodiment of a display apparatus according to the invention;

FIG. 2 is a schematic diagram illustrating a gate driving circuit as described in FIG. 1;

FIGS. 3A and 3B are circuit diagrams illustrating an odd-numbered stage and an even-numbered stage in FIG. 2;

FIG. 4 is a waveform diagram illustrating input and output signals of the gate driving circuit in FIG. 2;

FIG. 5 is a waveform diagram illustrating input and output signals of an exemplary embodiment of a gate driving circuit according to the invention;

FIG. 6 is a schematic diagram illustrating an exemplary embodiment of a gate driving circuit according to the invention; and

FIG. 7 is a waveform diagram illustrating input and output signals of the gate driving circuit in FIG. 6.

### DETAILED DESCRIPTION OF THE INVENTION

Hereinafter, the present invention will be explained in detail with reference to the accompanying drawings.

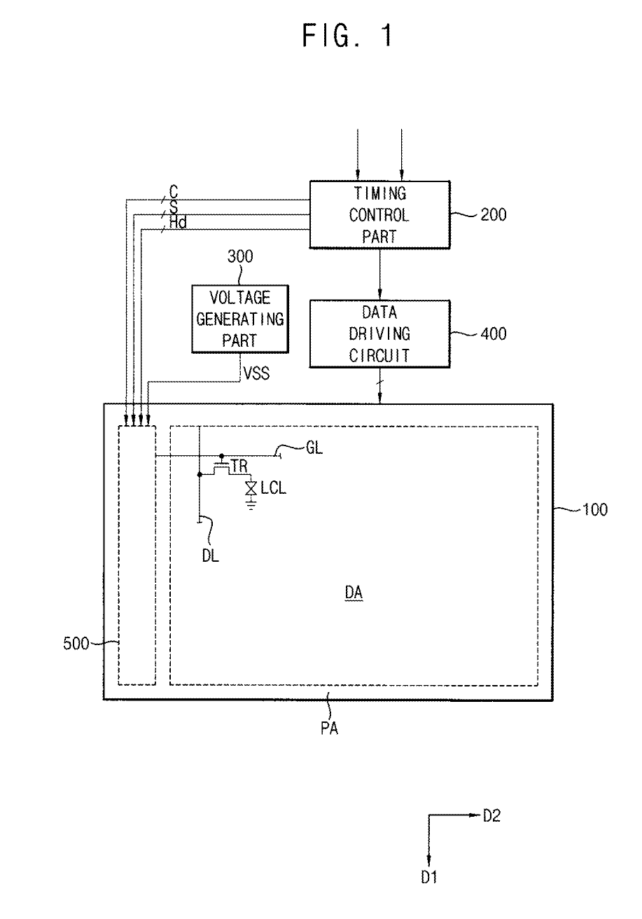

FIG. 1 is a block diagram illustrating an exemplary embodiment of a display apparatus according to the invention.

Referring to FIG. 1, the display apparatus includes a display panel 100, a timing control part 200, a voltage generating part 300, a data driving circuit 400 and a gate driving circuit 500.

The display panel 100 includes a display area DA and a peripheral area PA surrounding the display area DA.

A plurality of data lines DL, a plurality of gate lines GL and a plurality of pixels P are disposed in the display area DA. The data lines DL are extended in a first direction D1 and successive data lines DL are arranged in a second direction D2 crossing the first direction D1. The gate lines GL are extended in the second direction D2 and successive gate lines GL are arranged in the first direction D1. Each of the pixels P may include a thin film transistor TR connected to a data line DL and a gate line GL, and a liquid crystal capacitor CLC connected to the thin film transistor TR.

The gate driving circuit 500 is disposed in the peripheral area PA. The gate driving circuit 500 includes a plurality of signal lines and a plurality of thin film transistors. The gate driving circuit 500 may be formed in the peripheral area PA via a process or processes substantially the same as that for forming the thin film transistor TR disposed in the display area DA.

The timing control part 200 receives a synchronization signal and a data signal. The timing control part 200 generates a plurality of timing control signals based on the synchronization signal, corrects the data signal using various processes, and provides the data driving circuit 300 with the corrected data signal.

The timing control signal may include a data control signal for controlling a driving timing of the data driving circuit 400, and a gate control signal for controlling a driving timing of the gate driving circuit 500. The gate control signal may include a plurality of gate clock signals C, a plurality of gate selection signals S and a plurality of holding control signals Hd.

The voltage generating part 300 generates a driving voltage for driving the display panel 100. The driving voltage may include a gate-off voltage VSS, an analog driving voltage AVDD, a digital driving voltage DVDD and so on.

The data driving circuit 400 converts the data signal received from the timing control part 200 into a data voltage and provides the display panel 100 with the data voltage.

The gate driving circuit 500 includes a plurality of signal lines and a plurality of stages individually driven based on driving signals transferred from the signal lines. The signal lines transfer the driving signals for driving the stages, and the stages output a plurality of gate signals to the gate lines GL based on the driving signals. The signal lines include n clock lines CL and m selection lines SL (n and m are a natural number). The number of gate lines GL corresponds to n times m. For example, when the number of gate lines is 1080, the number n of the clock lines CL is 30 and the number m of the selection lines SL is 36. Thus, the number of clock lines and the number of selection lines may be variously designed corresponding to the number of the gate lines. Embodiments of the invention contemplate any number of clock lines and any number of selection lines.

The number of stages may be substantially the same as the number of the gate line, and each stage may include one or more thin film transistors.

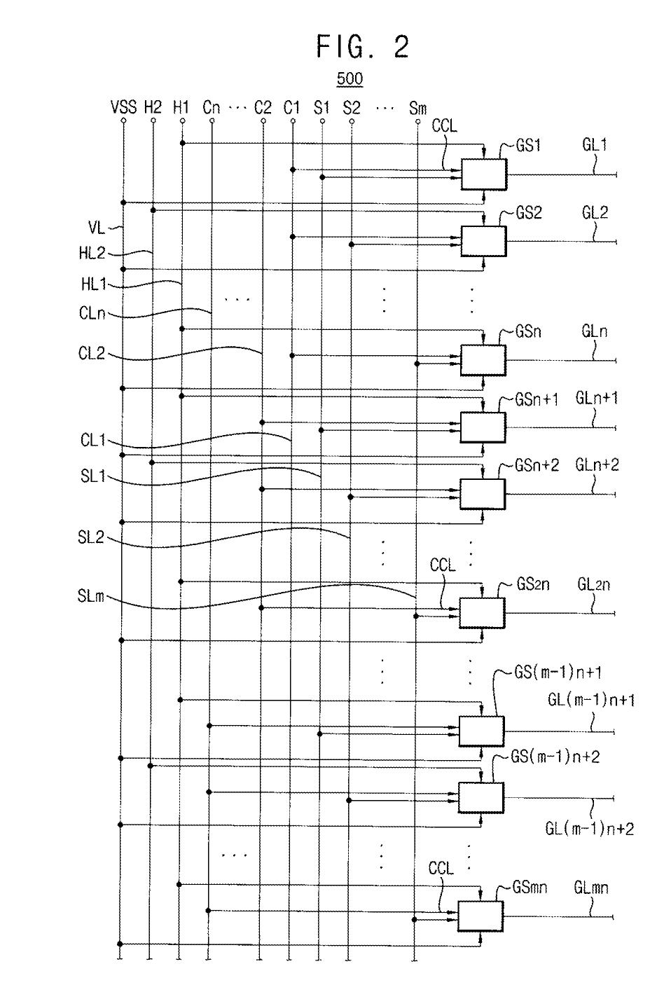

FIG. 2 is a schematic diagram illustrating a gate driving circuit in FIG. 1.

Referring to FIGS. 1 and 2, the gate driving circuit 500 includes a plurality of clock lines CL1, CL2, . . . , CLn, a plurality of selection lines SL1, SL2, . . . , SLm, holding control lines HL1 and HL2, a voltage line VL, and a plurality of stages GS1, GS2, . . . , GSnm.

First to n-th clock lines CL1, CL2, . . . , CLn respectively transfer first to n-th gate clock signals. Each clock line is connected to m stages which are continuously arranged (i.e., which are consecutive, or adjacent to each other). For example, a first clock line CL1 is connected to first to n-th stages GS1, GS2, . . . ,GSn, a second clock line CL2 is connected to (n+1)-th to 2n-th stages GSn+1, GSn+2, . . . , GS2n, an m-th clock line CLm is connected to [(m−1)n+1]-th to mn-th stags GS(m−1)n+1, GS(m−1)n+2, . . . , GSmn. Each of first to n-th clock lines CL1, CL2, . . . , CLn is electrically connected to the stages GS1, GS2, . . . , GSnm through a connection line CCL.

Each of the first to m-th gate clock signals includes a first pulse PW1 having a width corresponding to one horizontal period (1H). The first to n-th gate clock signals are transferred to the stages GS1, GS2, . . . , GSnm through lines having substantially the same resistance. For example, the first to n-th gate clock signals are received from pads disposed in the peripheral area of the display panel 100. The clock line and the connection line connected to the clock line are disposed between the pad and the stage. The cumulative resistance of the clock line and connection line connected to the clock line is substantially the same for each stage. According to position of each of the stages GS1, GS2, . . . , GSnm, a length sum of the clock line and the connection line connected to the clock line is different. This can be seen in FIG. 2. Thus, widths of the clock line and the connection line are adjusted, or lengths of the clock line and the connection line using a zigzag or another non-linear or irregular pattern are adjusted so that the first to n-th gate clock signals may be transferred to the stages GS1, GS2, . . . , GSnm through lines having substantially the same resistance.

First to m-th selection lines SL1, SL2, . . . , SLm respectively transfer first to m-th gate selection signals. Each selection line is connected to n stages which are discontinuously arranged (i.e. n stages which are not consecutive, or not adjacent to each other). For example, a first selection line SL1 is connected to a first, an (n+1)-th, a (2n+1)-th, . . . , an [(m−1)n+1]-th stage GS1, GSn+1, . . . , GS(m−1)n+1, a second selection line SL2 is connected to a second, a (n+2)-th, a (2n+2)-th, . . . , an [(m−1)n+2]-th stage GS2, GSn+2, . . . , GS(m−1)n+2, an n-th selection line SLn is connected to an n-th, a 2n-th, . . . , an mn-th stage GSn, GS2n, . . . , GSmn. Each of the first to n-th gate selection signals includes a second pulse PW2 having a width corresponding to n horizontal periods (n×H). The first pulse PW1 is repeated once each n horizontal periods (n×H), and the second pulse PW2 is repeated once for each frame.

The holding control line includes a first holding line HL1 transferring a first holding control signal and a second holding line HL2 transferring a second holding control signal. The first holding line HL1 is connected to the odd-numbered stages, and the second holding line HL2 is connected to the even-numbered stages. The first and second holding control signals have phases opposite to each other. The first holding control signal Hd1 controls odd-numbered gate signals outputted from the odd-numbered stages so that the odd-numbered gate signals are held at a gate-off voltage during each part of the frame except the one horizontal period during which the odd-numbered gate signal has a gate on voltage. The second holding control signal Hd2 controls even-numbered gate signals outputted from the even-numbered stages so that the even-numbered gate signal are held at a gate-off voltage during each part of the frame except the one horizontal period during which the even-numbered gate signal has a gate on voltage. The second holding control signal Hd2 has a phase opposite to a phase of the first holding control signal Hd1.

The voltage line VL transfers a gate-off voltage. The voltage line VL is connected to the first to mn-th stages GS1, GS2, . . . , GSmn.

Each of the first to mn-th stages GS1, GS2, . . . , GSmn includes a first input terminal, a second input terminal, a third input terminal, a fourth input terminal and an output terminal.

The first input terminal is connected to the clock line, the second input terminal is connected to the selection line, the third input terminal is connected to the holding control line, the fourth input terminal is connected to the voltage line and the output terminal is connected to the gate line.

The first to mn-th stages GS1, GS2, . . . , GSmn output gate signals based on the first to m-th gate selection signals and the first to m-th gate clock signals during one frame.

For example, the display panel for a full high definition (FHD) display may include 69 signal lines. The 69 signal lines include 36 clock lines transferring gate clock signals, 30 selection lines transferring gate selection signals, 2 holding control lines transferring holding control signals, and one voltage line transferring the gate-off voltage. In this case, when a width of each signal line is about 10 μm, a distance between those signal lines adjacent to each other is about 5 μm, and the width of the area in which the gate driving circuit with the 69 signal lines is formed is about 1.3 mm. In contrast, the width of the area in which the gate driving circuit with 17 thin film transistors is formed is about 3.4 mm. Thus, according to the present exemplary embodiment, the width of the area in which the gate driving circuit is formed may be decreased by about 2.1 mm. Therefore, the display apparatus according to the present exemplary embodiment may have a narrower bezel width.

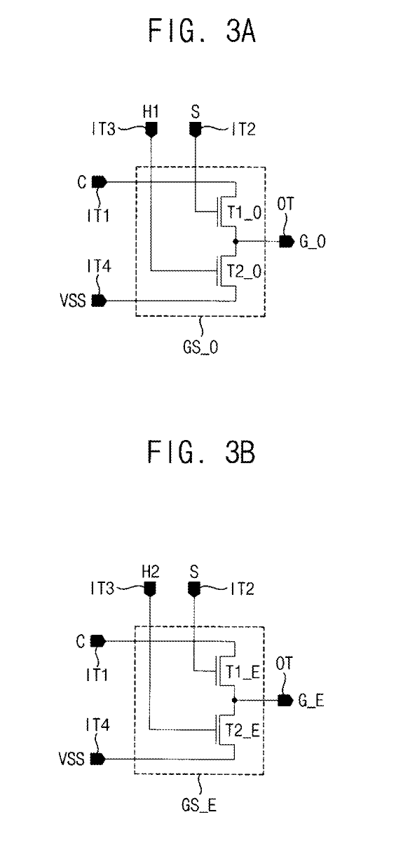

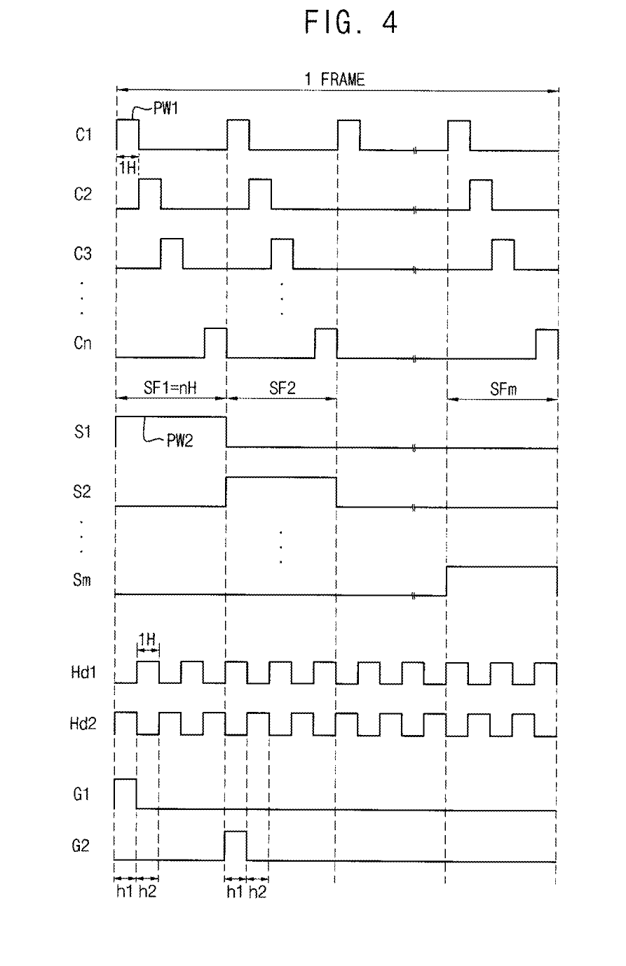

FIGS. 3A and 3B are circuit diagrams illustrating an odd-numbered stage and an even-numbered stage in FIG. 2. FIG. 4 is a waveform diagram illustrating input and output signals of the gate driving circuit in FIG. 2.

Referring to FIGS. 2, 3A, 3B and 4, each odd-numbered stage GS_O includes a first transistor T1_O, a second transistor T2_O, a first input terminal IT1, a second input terminal IT2, a third input terminal IT3, a fourth input terminal IT4 and an output terminal OT.

The first transistor T1_O includes a control part connected to the second input terminal IT2, an input part connected to the first input terminal IT1 and an output part connected to the output terminal OT.

The second transistor T2_O includes a control part connected to the third input terminal IT3, an input part connected to the fourth input terminal IT4 and an output part connected to the output part of the first transistor T1_O.

The first input terminal IT1 receives the gate clock signal. The gate clock signal in general includes first to n-th gate clock signals C1, C2, . . . , Cn. The first to n-th gate clock signals C1, C2, . . . , Cn are sequentially delayed by one horizontal period (1H) and have a high voltage and a low voltage. The high voltage of the gate clock signal may be about 30 V, and the low voltage of the gate clock signal may be about −7.5V.

For example, when the odd-numbered stage is a first stage GS1, the first input terminal IT1 receives a first gate clock signal C1.

The second input terminal IT2 receives the gate selection signal. The gate selection signal in general includes first to m-th gate selection signals S1, S2, . . . , Sm. The first to m-th gate selection signals S1, S2, . . . , Sm are sequentially delayed by n horizontal periods (n×H) and have a high voltage and a low voltage. The high voltage of the gate selection signal may be about 45 V, and the low voltage of the gate selection signal may be about −7.5V. For example, when the odd-numbered stage is the first stage GS1, the second input terminal IT2 receives a first gate selection signal S1.

The third input terminal IT3 receives the first holding control signal Hd1.

The fourth input terminal IT4 receives the gate-off voltage VSS.

The output terminal OT is connected to the gate line, and outputs the gate signal G1 having a gate-on voltage and a gate-off voltage.

For example, when the odd-numbered stage is the first stage GS1, the first input terminal IT1 receives the first gate clock signal C1, the second input terminal IT2 receives the first gate selection signal S1, the third input terminal IT3 receives the first holding control signal Hd1 and the fourth input terminal IT4 receives the gate-off voltage VSS.

The first transistor T1_O outputs the high voltage of the first gate clock signal through the output terminal OT during a first period h1 during which the first gate selection signal S1 has the high voltage C1, wherein the first period h1 is included in a first sub period SF1. Thus, the first stage GS1 outputs the high voltage of the first gate clock signal C1 as the gate-on voltage of a first gate signal G1.

The second transistor T2_O outputs the gate-off voltage VSS through the output terminal OT during a second period h2 of the first sub period SF1 in response to the high voltage of the first holding control signal Hd1. Thus, the first stage GS1 outputs the gate-off voltage VSS as the gate-off voltage of a first gate signal G1.

During the remaining periods of the frame besides the first period h1, the second transistor T2_O outputs the gate-off voltage VSS as the gate-off voltage of the first gate signal G1 in response to the high voltage of the first holding control signal Hd1.

Each even-numbered stage GS_E includes a first transistor T1_E, a second transistor T2_E, a first input terminal IT1, a second input terminal IT2, a third input terminal IT3, a fourth input terminal IT4 and an output terminal OT.

The first transistor T1_E includes a control part connected to the second input terminal IT2, an input part connected to the first input terminal IT1 and an output part connected to the output terminal OT.

The second transistor T2_E includes a control part connected to the third input terminal IT3, an input part is connected to the fourth input terminal IT4 and an output part connected to the output part of the first transistor T1_E.

The first input terminal IT1 receives the gate clock signal. For example, when the even-numbered stage is the first stage GS2, the first input terminal IT1 receives a first gate clock signal C1.

The second input terminal IT2 receives the gate selection signal. For example, when the even-numbered stage is the second stage GS2, the second input terminal IT2 receives the second gate selection signal S2.

The third input terminal IT3 receives a second holding control signal Hd2.

The fourth input terminal IT4 receives the gate-off voltage VSS.

The output terminal OT is connected to the gate line, and outputs the gate signal having the gate-on voltage and the gate-off voltage.

For example, when the even-numbered stage is the second stage GS2, the first input terminal IT1 receives the first gate clock signal C1, the second input terminal IT2 receives the second gate selection signal S2, the third input terminal IT3 receives a second holding control signal Hd2 and the fourth input terminal IT4 receives the gate-off voltage VSS.

The first transistor T1_E outputs the high voltage of the first gate clock signal C1 in response to the high voltage of the second gate selection signal S2 through the output terminal OT during a first period h1 during which the second gate selection signal S2 has the high voltage, wherein the first period h1 is included in the second sub period SF2. The second stage GS2 outputs the high voltage of the first gate clock signal C1 as the gate-on voltage of a second gate signal G2.

The second transistor T2_E outputs the gate-off voltage VSS through the output terminal OT during a second period h2 of the second sub period SF2 in response to the high voltage of the second holding control signal Hd2. The second stage GS2 outputs the gate-off voltage VSS as the gate-off voltage of the second gate signal G2.

During the remaining period of the frame aside from the first period h1, the second transistor T2_E outputs the gate-off voltage VSS as the gate-off voltage of the second gate signal G2 in response to the high voltage of the second holding control signal Hd2.

According to the present exemplary embodiment, the gate driving circuit 500 sequentially outputs first, (n+1)-th, (2n+1)-th, . . . , [(m−1)n+1]-th gate signals during the first sub period SF1 during which the first gate selection signal Si has the high voltage. The gate driving circuit 500 also sequentially outputs second, (n+2)-th, (2n+2)-th, . . . , [(m−1)n+2]-th gate signals during the second sub period SF2 during which the second gate selection signal S2 has the high voltage. The gate driving circuit 500 sequentially outputs n-th, 2n-th, . . . , mn-th gate signals during the m-th sub period SFm during which an m-th gate selection signal Sm has the high voltage.

Therefore, the gate driving circuit 500 outputs first to mn-th gate signals G1, G2, G3, . . . , Gmn during one frame.

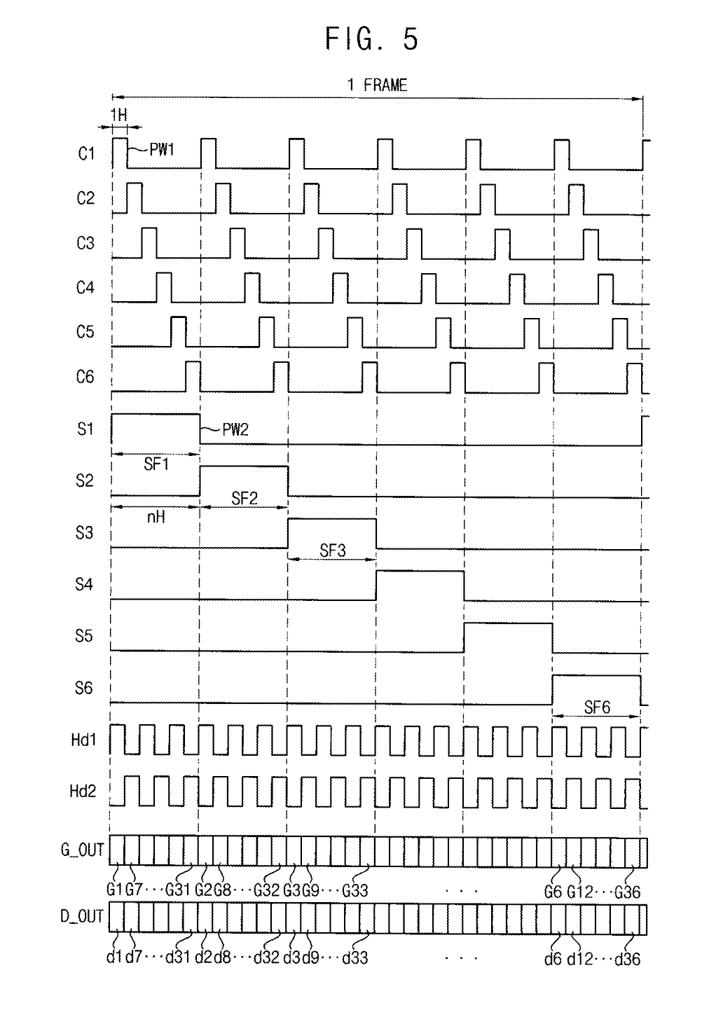

FIG. 5 is a waveform diagram illustrating input and output signals of an exemplary embodiment of a gate driving circuit according to the invention.

Referring to FIGS. 1, 2 and 5, the gate driving circuit according to the present exemplary embodiment drives 36 gate lines, so that the number of gate clock signals may be six and the number of gate selection signals may also be six.

The timing control part 200 provides the gate driving circuit 500 with a gate control signal which includes first to sixth gate clock signals C1, C2, . . . , C6, first to sixth gate selection signals S1, S2, . . . , S6, and first and second holding control signals Hd1 and Hd2.

In addition, the timing control part 200 controls the data driving circuit 400 so that the data driving circuit 400 is driven in synchronization with the gate driving circuit 500. For example, the data driving circuit 400 outputs data signals to pixels connected to a first gate line GL1 in a horizontal period during which the gate driving circuit 500 outputs the gate-on voltage of the first gate signal G1 to the first gate line GL1.

Referring to FIGS. 3A and 3B, the gate driving circuit 500 generates first, seventh, thirteenth, nineteenth, twenty-fifth and thirty-first gate signals G1, G7, G13, G19, G25, and G31 using the high voltage of first to sixth gate clock signals C1, C2, . . . , C6 sequentially received from the timing control part 200, in response to the high voltage of the first gate selection signal S1. The gate driving circuit 500 sequentially outputs first, seventh, thirteenth, nineteenth, twenty-fifth and thirty-first gate signals G1, G7, G13, G19, G25, and G31 to the first, seventh, thirteenth, nineteenth, twenty-fifth and thirty-first gate lines during the first sub period SF1 during which the first gate selection 51 goes high (G_OUT).

The data driving circuit 400 sequentially provides the display panel 100 with line data signals d1, d7, d13, d19, d25, and d31 respectively corresponding to first, seventh, thirteenth, nineteenth, twenty-fifth and thirty-first horizontal lines in synchronization with the gate driving circuit 500 (D_OUT).

During the second sub period SF2 during which the second gate selection signal S2 has the high voltage, the gate driving circuit 500 generates second, eighth, fourteenth, twentieth, twenty-sixth, and thirty-second gate signals G2, G8, G14, G20, G26, G32 using the high voltage of first to sixth gate clock signals C1, C2, . . . , C6 sequentially received from the timing control part 200, in response to the high voltage of the second gate selection signal S2. During the second sub period SF2, the gate driving circuit 500 sequentially outputs second, eighth, fourteenth, twentieth, twenty-sixth, and thirty-second gate signals G2, G8, G14, G20, G26, G32 to the second, eighth, fourteenth, twentieth, twenty-sixth, and thirty-second gate lines (GOUT).

The data driving circuit 400 sequentially provides the display panel 100 with line data signals d2, d8, d14, d20, d26, and d32 respectively corresponding to second, eighth, fourteenth, twentieth, twenty-sixth, and thirty-second horizontal lines in synchronization with the gate driving circuit 500 (D_OUT).

As described above, during the sixth sub period SF6 during which the sixth gate selection signal S6 has the high voltage, the gate driving circuit 500 generates sixth, twelfth, eighteenth, twenty-fourth, thirtieth, and thirty-sixth gate signals G6, G12, G18, G24, G30, and G36 using the high voltage of first to sixth gate clock signals C1, C2, . . . , C6 sequentially received from the timing control part 200, in response to the high voltage of the second gate selection signal S2. During the second sub period SF2, the gate driving circuit 500 sequentially outputs sixth, twelfth, eighteenth, twenty-fourth, thirtieth, and thirty-sixth gate signals G6, G12, G18, G24, G30, and G36 to sixth, twelfth, eighteenth, twenty-fourth, thirtieth, and thirty-sixth gate lines (GOUT).

The data driving circuit 400 sequentially provides the display panel 100 with line data signals d6, d12, d18, d24, d30, and d36 respectively corresponding to sixth, twelfth, eighteenth, twenty-fourth, thirtieth, and thirty-sixth horizontal lines in synchronization with the gate driving circuit 500 (D_OUT).

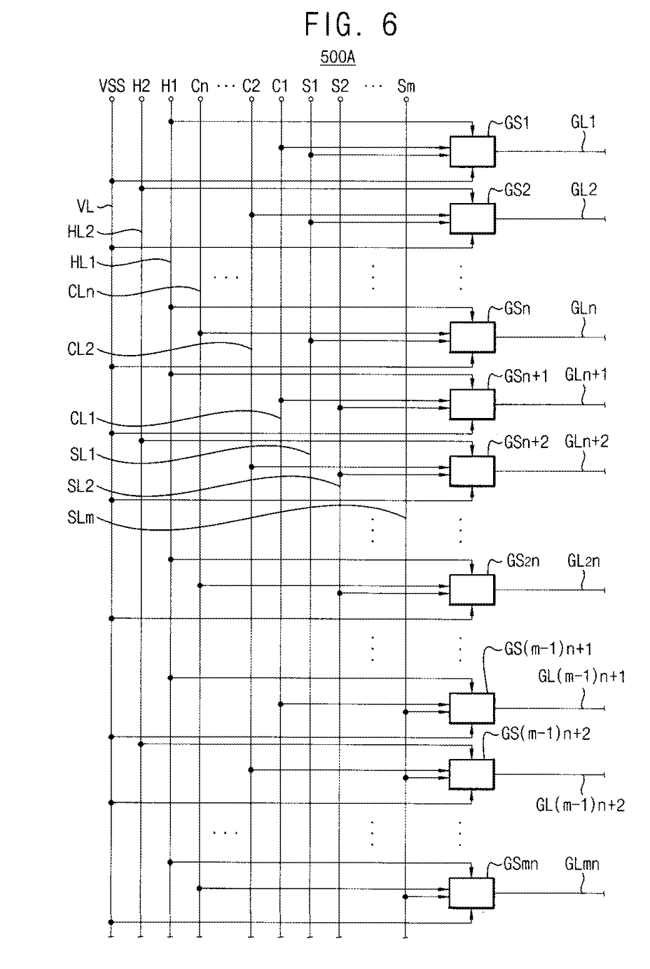

FIG. 6 is a schematic diagram illustrating an exemplary embodiment of a gate driving circuit according to the invention.

Referring to FIGS. 1 and 6, the gate driving circuit 500A according to the present exemplary embodiment is substantially the same as the gate driving circuit 500 according to the previous exemplary embodiment shown in FIG. 2, except for a connection relation of a plurality of stages GS1, GS2, . . . , GSnm, first to n-th clock lines CL1, CL2, . . . , CLn and first to m-th selection lines SL1, SL2, . . . , SLm. Hereinafter, the same reference numerals are used to refer to the same or like parts as those described in the previous exemplary embodiments, and the same detailed explanations are not repeated unless necessary.

For example, first to n-th clock lines CL1, CL2, . . . , CLn respectively transfer first to n-th gate clock signals. Each clock line is connected to m stages which are discontinuously arranged. For example, a first clock line CL1 is connected to first, (n+1)-th, (2n+1)-th, . . . , [(m−1)n+1]-th stages GS1, GSn+1, GS2n+1, . . . , GS(m−1)n+1, a second clock line CL2 is connected to second, (n+2)-th, (2n+2)-th, . . . , [(m−1)n+2]-th stages GS2, GSn+2, GS2n+2, . . . , GS(m−1)n+2, and an m-th clock line CLm is connected to n-th, 2n-th, . . . , mn-th stages GSn, GS2n, . . . , GSmn. Each of the first to n-th clock lines CL1, CL2, . . . , CLn, which is extended in a column direction, is electrically connected to the stages GS1, GS2, . . . , GSnm through connection lines which are extended in a row direction.

First to m-th selection lines SL1, SL2, . . . , SLm respectively transfer first to m-th gate selection signals. Each selection line is connected to n stages which are continuously arranged. For example, a first selection line SL1 is connected to first to n-th stages GS1, GS2, . . . , GSn, a second selection line SL2 is connected to (n+1)-th to 2n-th stages GSn+1, GSn+2, . . . , GS2n, an n-th selection line SLn is connected to [(m−1)n+1]-th to mn-th stages GS(m−1)n+1, GS(m−1)n+2, . . . , GSmn. Each of the first to n-th gate selection signals includes a second pulse PW2 having a pulse width corresponding to n horizontal periods (n×H), and for each selection line SLm, the second pulse PW2 occurs once per frame.

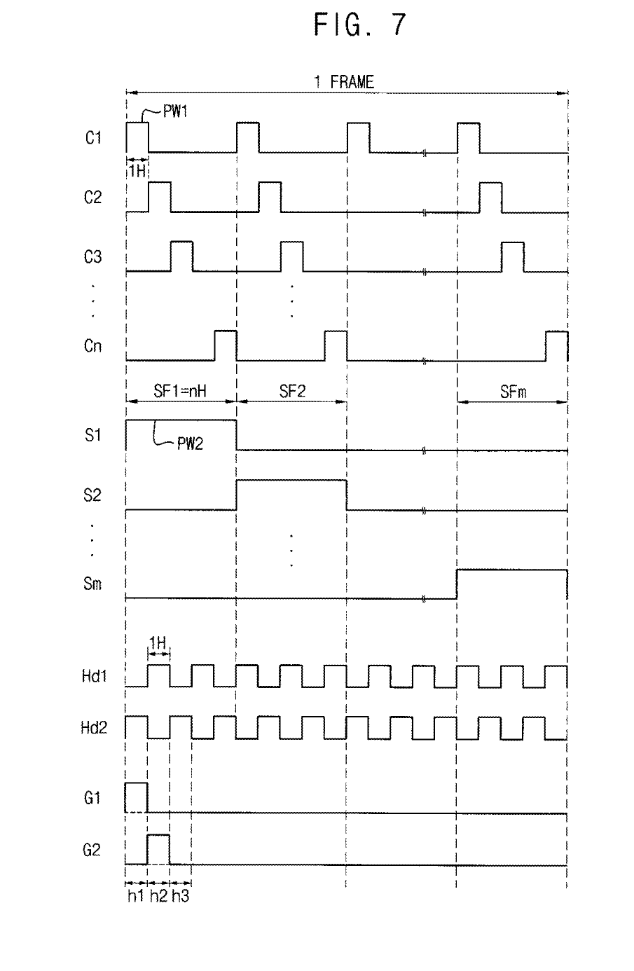

FIG. 7 is a waveform diagram illustrating input and output signals of the gate driving circuit in FIG. 6.

Referring to FIGS. 3A, 3B, 6 and 7, when the odd-numbered stage is the first stage GS1, the first input terminal IT1 receives the first gate clock signal C1, the second input terminal IT2 receives the first gate selection signal S1, the third input terminal IT3 receives the first holding control signal Hd1, and the fourth input terminal IT4 receives the gate-off voltage VSS.

The first transistor T1_O outputs the high voltage of the first gate clock signal through the output terminal OT during a first period h1 during which the first gate selection signal S1 has the high voltage C1, wherein the first period h1 is included in a first sub period SF1. The first stage GS1 outputs the high voltage of the first gate clock signal C1 as the gate-on voltage of a first gate signal G1.

The second transistor T2_O outputs the gate-off voltage VSS through the output terminal OT during a second period h2 of the first sub period SF1 in response to the high voltage of the first holding control signal Hd1. The first stage GS1 thus outputs the gate-off voltage VSS as the gate-off voltage of the first gate signal G1.

During the remainder of the frame besides the first period h1, the second transistor T2_O outputs the gate-off voltage VSS as the gate-off voltage of the first gate signal G1 in response to the high voltage of the first holding control signal Hd1.

In addition, when the even-numbered stage is the second stage GS2, the first input terminal IT1 receives the second gate clock signal C2, the second input terminal IT2 receives the first gate selection signal S1, the third input terminal IT3 receives a second holding control signal Hd2 and the fourth input terminal IT4 receives the gate-off voltage VSS.

The first transistor T1_E outputs the high voltage of the second gate clock signal C2 in response to the high voltage of the first gate selection signal S1 through the output terminal OT during a second period h2, wherein the second period h2 is included in the first sub period SF1. The second stage GS2 outputs the high voltage of the second gate clock signal C2 as the gate-on voltage of a second gate signal G2.

The second transistor T2_E outputs the gate-off voltage VSS through the output terminal OT during a third period h3 of the first sub period SF1 in response to the high voltage of the second holding control signal Hd2. The second stage GS2 outputs the gate-off voltage VSS as the gate-off voltage of the second gate signal G2.

During the remainder of the frame besides the second period h2, the second transistor T2_E outputs the gate-off voltage VSS as the gate-off voltage of the second gate signal G2 in response to the high voltage of the second holding control signal Hd2.

According to the present exemplary embodiment, the gate driving circuit 500A sequentially outputs first to n-th gate signals during the first sub period SF1 during which the first gate selection signal S1 has the high voltage. The gate driving circuit 500A sequentially outputs (n+1)-th to 2n-th gate signals during the second sub period SF2 during which the second gate selection signal S2 has the high voltage. The gate driving circuit 500A sequentially outputs [(m−1)n+1]-th to mn-th gate signals during the m-th sub period SFm during which an m-th gate selection signal Sm has the high voltage.

Therefore, the gate driving circuit 500A sequentially outputs first to mn-th gate signals G1, G2, G3, . . . , Gmn during one frame.

A data driving circuit according to the present exemplary embodiment may sequentially provide horizontal lines of the display panel with data signals in synchronization with the gate driving circuit 500A.

According to the exemplary embodiments, the gate driving circuit includes only two thin film transistors, so that an area in which the gate driving circuit is formed may be decreased. Therefore, the display apparatus may have a narrow bezel width.

The foregoing is illustrative of the present invention and is not to be construed as limiting thereof. Although a few exemplary embodiments of the present invention have been described, those skilled in the art will readily appreciate that many modifications are possible in the exemplary embodiments without materially departing from the novel teachings and advantages of the present invention, including combining various aspects of different embodiments with each other. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of the present invention and is not to be construed as limited to the specific exemplary embodiments disclosed, and that modifications to the disclosed exemplary embodiments, as well as other exemplary embodiments, are intended to be included within the scope of the appended claims. The present invention is defined by the following claims, with equivalents of the claims to be included therein.

What is claimed is:

1. A gate driving circuit comprising:
first to n-th gate clock lines configured to transfer first to n-th gate clock signals (‘n’ is a natural number);
first to m-th selection lines configured to transfer first to m-th gate selection signals (‘m’ is a natural number);
a holding control line configured to transfer a holding control signal;
a voltage line configured to transfer a gate-off voltage; and
a plurality of stages configured to output a plurality of gate signals, each stage configured to output a high voltage of one of the gate clock signals as a gate-on voltage of a gate signal in response to a high voltage of one of the gate selection signals, and configured to output the gate-off voltage in response to a high voltage of the holding control signal.

2. The gate driving circuit of claim 1, wherein each stage comprises:
a first transistor comprising a control part configured to receive one of the gate selection signals, an input part configured to receive one of the gate clock signals and an output configured to output one of the gate signals; and
a second transistor comprising a control part configured to receive the holding control signal, an input part configured to receive the gate-off voltage and an output part configured to output one of the gate signals.

3. The gate driving circuit of claim 2, wherein the holding control line comprises:
a first holding line electrically connected to an odd-numbered one of the stages to transfer a first holding control signal; and
a second holding line electrically connected to an even-numbered one of the stages to transfer a second holding control signal having a phase opposite to a phase of the first holding control signal.

4. The gate driving circuit of claim 2, wherein the gate clock signals each comprise a first pulse having a width corresponding to one horizontal period, and the gate selection signals each comprise a second pulse having a width corresponding to n horizontal periods.

5. The gate driving circuit of claim 4, wherein ones of the first pulses are successively emitted during each of n consecutive horizontal periods, and the second pulses are collectively emitted during one frame period.

6. The gate driving circuit of claim 4, wherein successive ones of the first to n-th gate clock signals are sequentially delayed by one horizontal period, and successive ones of the first to m-th gate selection signals are sequentially delayed by n horizontal periods.

7. The gate driving circuit of claim 1, wherein the high voltage of the gate selection signal is higher than the high voltage of the gate clock signal.

8. The gate driving circuit of claim 1, wherein each of the gate clock lines is connected to m consecutive stages and each selection line is connected to n stages which are not consecutive.

9. The gate driving circuit of claim 1, wherein each of the gate clock lines is connected to m stages which are not consecutive and each selection line is connected to n consecutive stages.

10. A display apparatus comprising:
a display panel including a display area and a peripheral area surrounding the display area, the display panel including a plurality of data lines and a plurality of gate lines crossing the data lines;
a data driving circuit configured to provide the data lines with data signals; and
a gate driving circuit disposed in the peripheral area, the gate driving circuit configured to provide the gate lines with a plurality of gate signals, the gate driving circuit comprising:
first to n-th gate clock lines configured to transfer first to n-th gate clock signals (‘n’ is a natural number);
first to m-th selection lines configured to transfer first to m-th gate selection signals (‘m’ is a natural number);
a holding control line configured to transfer a holding control signal;
a voltage line configured to transfer a gate-off voltage; and
a plurality of stages configured to output a plurality of gate signals, each stage configured to output a high voltage of one of the gate clock signals as a gate signal in response to a high voltage of one of the gate selection signals, and configured to output the gate-off voltage in response to a high voltage of the holding control signal.

11. The gate driving circuit of claim 10, further comprising:
a timing control part configured to provide the gate driving circuit with the gate clock signals, the gate selection signals and the holding control signal.

12. The gate driving circuit of claim 10, wherein the gate driving circuit is configured to sequentially provide the display panel with m gate signals during a sub period during which the gate selection signal has a high voltage, and
the data driving circuit is configured to provide the data signals to pixels during the sub period, the pixels being connected to n gate lines which receive n gate signals.

13. The gate driving circuit of claim 10, wherein each stage comprises:
a first transistor comprising a control part configured to receive the gate selection signal, an input part configured to receive the gate clock signal and an output part configured to output the gate signal; and
a second transistor comprising a control part configured to receive the holding control signal, an input part configured to receive the gate low voltage and an output part configured to output the gate signal.

14. The gate driving circuit of claim 13, wherein the holding control line comprises:
a first holding line electrically connected to odd-numbered ones of the stages, the first holding line configured to transfer a first holding control signal; and
a second holding line electrically connected to even-numbered ones of the stages, the second holding line configured to transfer a second holding control signal having a phase opposite to the first holding control signal.

15. The gate driving circuit of claim 13, wherein the gate clock signals each comprise a first pulse having a width corresponding to one horizontal period, and the gate selection signals each comprise a second pulse having a width corresponding to n horizontal periods.

16. The gate driving circuit of claim 15, wherein ones of the first pulses are successively emitted during each of n consecutive horizontal periods, and the second pulses are collectively emitted during one frame period.

17. The gate driving circuit of claim 15, wherein successive ones of the first to n-th gate clock signals are sequentially delayed by one horizontal period, and successive ones of the first to m-th gate selection signals is sequentially delayed by n horizontal periods.

18. The gate driving circuit of claim 10, wherein the high voltage of the gate selection signal is higher than the high voltage of the gate clock signal.

19. The gate driving circuit of claim 10, wherein each of the clock lines is connected to m consecutive stages and each selection line is connected to n stages which are not consecutive.

20. The gate driving circuit of claim 10, wherein each of the clock lines is connected to m stages which are not consecutive and each selection line is connected to n consecutive stages.
